(19) United States
(12) Patent Application Publication
(10) Pub. No.: US 2024/0145429 A1
(43) Pub. Date: May 2, 2024

(54) METHOD OF MANUFACTURING SEMICONDUCTOR DEVICES, CORRESPONDING LEADFRAME, MOLD AND SEMICONDUCTOR DEVICE

(71) Applicant: STMICROELECTRONICS S.r.l., Agrate Brianza (IT)

(72) Inventors: Riccardo VILLA, Milano (IT); Guendalina CATALANO, Milano (IT)

(73) Assignee: STMICROELECTRONICS S.r.l., Agrate Brianza (IT)

(21) Appl. No.: 18/496,634

(22) Filed: Oct. 27, 2023

(30) Foreign Application Priority Data
Nov. 2, 2022 (IT) 102022000022443

(51) Int. Cl. H01L 23/00; H01L 21/56; H01L 23/31; H01L 23/495

(52) U.S. Cl. CPC H01L 24/82; H01L 21/561; H01L 23/3135; H01L 23/49513; H01L 24/24; H01L 24/32; H01L 24/73; H01L 24/92; H01L 2224/24105; H01L 2224/24247; H01L 2224/245; H01L 2224/32245; H01L 2224/73267; H01L 2224/82101; H01L 2224/82103; H01L 2224/92244; H01L 2924/01029

(57) ABSTRACT

Laser direct structuring, LDS material is molded onto semiconductor dice arranged on die pads in a leadframe and the semiconductor dice are electrically coupled with electrically conductive leads in the leadframe via electrical connections that comprise electrically conductive formations exposed at the front surface of the LDS material, electrically conductive vias between the semiconductor dice and the front surface of the LDS material, as well as electrically conductive lines over the front surface of the LDS material that couple selected ones of the electrically conductive formations with selected ones of the second electrically conductive vias. The electrically conductive vias and lines are provided applying laser beam energy to the front surface of the laser direct structuring material at spatial positions located as a function of the electrically conductive formations exposed at the front surface of the LDS material acting as fiducials. The electrically conductive formations exposed at the front surface of the LDS material may comprise pillar-like extensions of the leadframe leads, electrically conductive material grown on the leads in cavities in the front surface of the LDS material or electrically conductive leads in a lead frame where the die pads are downset with respect to the leads.

### BACKGROUND

### Technical Field

The description relates to manufacturing semiconductor devices.

One or more embodiments may be applied to manufacturing semiconductor devices including integrated circuits (ICs), for instance.

### Description of the Related Art

Laser direct structuring or LDS represents a laser-based technology now used in manufacturing semiconductor devices wherein electrically conductive formations such as lines and vias can be formed in an otherwise insulating molding compound via laser beam activation or “structuring” followed by metallization.

Through Mold Via (TMV) laser drilling through LDS compound is facilitated by alignment with respect to die bonding pad and leads; in fact, mounting chips or dice on a substrate (leadframe) and the subsequent compressive molding may cause shrinkage of the leadframe and an uncontrolled misalignment of the die bonding pads and the leadframe with respect to an outer frame reference.

Moreover, the molding compound hides or masks the die bonding pads and the leads and the laser unit may end up by operating in a kind of “blind mode”.

Enabling a laser unit used for activating (structuring) the LDS material to have precise knowledge of the actual position of a semiconductor die (chip)—even if the semiconductor die is somehow “hidden” by a molding compound layer—facilitates effectively replacing wire bonding technology with LDS technology.

Existing solutions for that purpose, like mounting X-ray imaging devices on laser machining devices or providing protruding structures on top of the die, may be unpractical or too costly.

### BRIEF SUMMARY

The present disclosure provides one or more embodiments to overcome the drawbacks discussed in the foregoing, thus facilitating application of laser direct structuring (LDS) technology to manufacturing semiconductor devices.

One or more embodiments relate to a leadframe for use in solutions as described herein.

One or more embodiments relate to a mold for use in solutions as described herein.

One or more embodiments relate to a corresponding semiconductor device.

Solutions as described herein involve leaving portions of the leadframe exposed on the surface of the molding compound, thus providing “fiducials” for the alignment of the laser unit.

Solutions as described herein involve providing protrusions on the surface of the leadframe.

Solutions as described herein involve the insertion of punches during the molding step.

### BRIEF DESCRIPTION OF THE SEVERAL VIEWS OF THE DRAWINGS

One or more embodiments will now be described, by way of example only, with reference to the attached figures, wherein:

FIGS. 1A to 1D are exemplary of a sequence of steps in manufacturing a semiconductor device using LDS technology,

FIGS. 2A to 2F are illustrative of a sequence of steps in a first embodiment of the present description,

FIGS. 3A to 3F are illustrative of a sequence of steps in a second embodiment of the present description, and

FIGS. 4A to 4F are illustrative of a sequence of steps in a third embodiment of the present description.

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

### DETAILED DESCRIPTION

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments. The references used herein are provided merely for convenience and hence do not define the extent of protection or the scope of the embodiments.

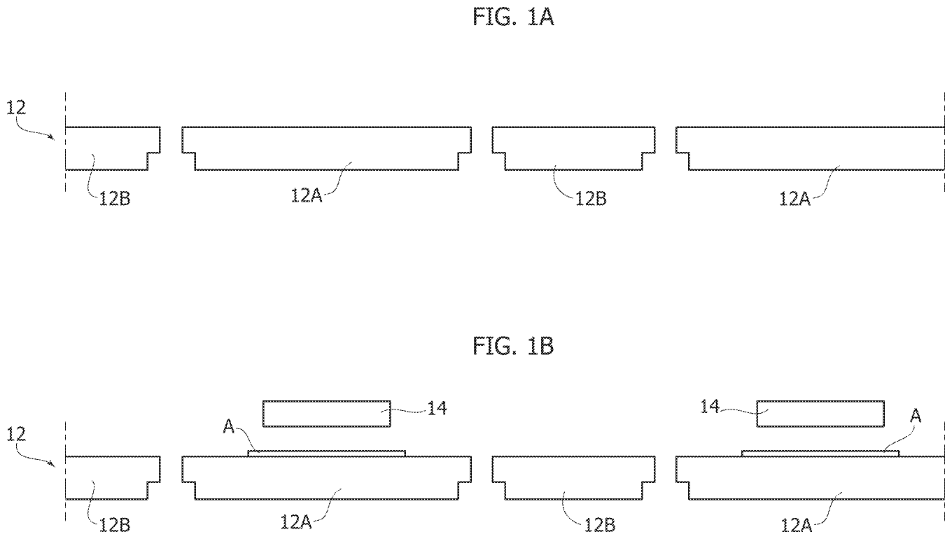

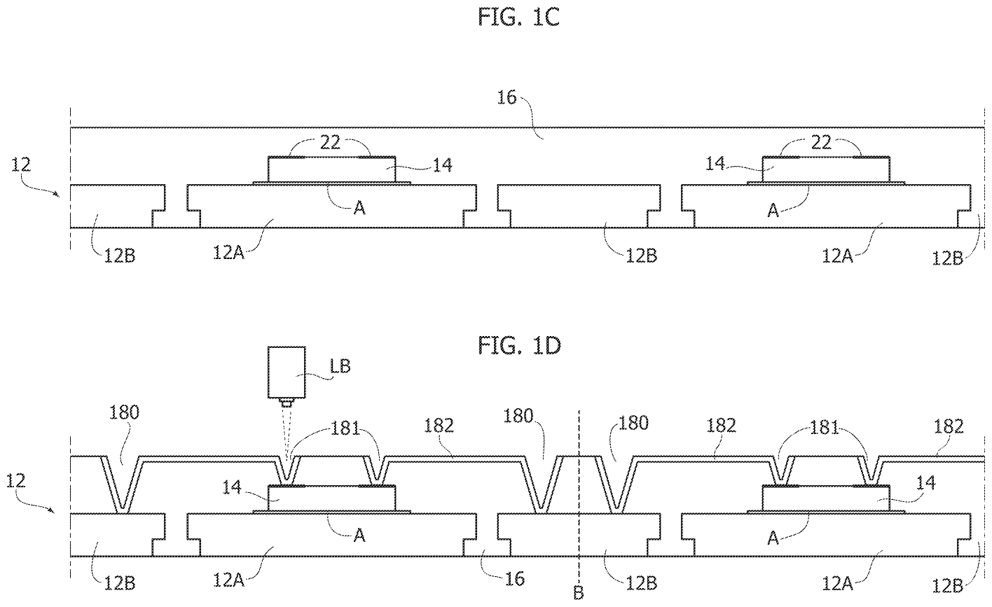

The sequence of FIGS. 1A to 1D reproduces steps in manufacturing a semiconductor device via Laser Direct Structuring (LDS) technology.

LDS is a laser-based machining technique now widely used in various sectors of the industrial and consumer electronics markets, for instance for high-performance antenna integration, where an antenna design can be directly formed onto a molded plastic part. In an exemplary process, the molded parts can be produced with commercially available insulating resins that include additives suitable for the LDS process; a broad range of resins such as polymer resins like PC, PC/ABS, ABS, LCP are currently available for that purpose. A laser beam can be used to transfer (“structure”) a desired electrically conductive pattern onto a plastic molding that may then be subjected to metallization to finalize a desired conductive pattern.

Metallization may involve electroless plating followed by electrolytic plating. Electroless plating, also known as chemical plating, is a class of industrial chemical processes that creates metal coatings on various materials by autocatalytic chemical reduction of metal cations in a liquid bath. In electrolytic plating, an electric field between an anode and a workpiece, acting as a cathode, forces positively charged metal ions to move to the cathode where they give up their charge and deposit themselves as metal on the surface of the workpiece.

LDS is oftentimes referred to also as direct copper interconnection, DCI. This is primarily with reference to a package family wherein conventional wire bonding is replaced with copper plated vias and lines (traces). Laser Induced Strip Interconnection, LISI is another designation used for DCI packages where LDS technology is used for creating vias and traces in a resin.

Documents such as US 2018/342453 A1, US2019/115287 A1, US 2020/203264 A1, US 2020/321274 A1, US 2021/050226 A1, US 2021/050299 A1, US 2021/183748 A1, or US 2021/305203 A1 (all assigned to the same assignee of the present application) are exemplary of the possibility of applying LDS technology in manufacturing semiconductor devices.

A conventional semiconductor device manufacturing process as illustrated in FIGS. 1A to 1D involves arranging one or more semiconductor integrated circuit chips or dice onto a substrate (leadframe) 12.

As used herein, the terms chip/s and die/dice are regarded as synonymous.

The chip(s), indicated by reference 14, are attached on one or more die pads 12A in the leadframe 12, with an array of leads 12B around the die pads 12A.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Essentially, a leadframe comprises an array of electrically-conductive formations (or leads, e.g., 12B) that from an outline location extend inwardly in the direction of an (integrated circuit) semiconductor chip or die (e.g., 14) thus forming an array of electrically-conductive formations from a die pad (e.g., 12A) configured to have at least one semiconductor chip or die attached thereon. This may be via conventional means such as a die attach adhesive A (a die attach film or DAF, for instance).

Electrically conductive formations are provided to electrically couple the semiconductor chip(s) 14 to selected ones of the leads (outer pads) 12B in the leadframe 12.

Such coupling can be provided via wire-bonding, as conventional in the art.

FIGS. 1A to 1D are illustrative of such coupling being provided (as an alternative to wire-bonding) via Laser Direct Structuring or LDS (DCI) technology.

As noted, LDS technology facilitates replacing wires, clips or ribbons with lines/vias created by laser beam processing of an LDS material followed by metallization (growing metal such as copper via a plating process, for instance).

Electrically conductive die-to-lead coupling formations can be provided in the LDS material (once consolidated, e.g., via thermosetting).

In current manufacturing processes of semiconductor devices, plural devices are manufactured concurrently to be separated into single individual devices in a final singulation step (e.g., via a blade as indicated by B in FIG. 1D).

In the sequence of FIGS. 1A to 1D:

FIG. 1A illustrates a leadframe 12 strip being provided including die pads 12A and leads 12B;

FIG. 1B is illustrative of dice 14 being mounted (e.g., attached via die attach film or DAF) on the die pads 12A in the leadframe 12;

FIG. 1C illustrates a (compressive) molding step wherein LDS material 16 is molded on the assembly of FIG. 1B; and

FIG. 1D is illustrative of regions 180, 181 and 182 being “structured” (“activated”) via a laser beam LB in the material 16. Such structuring involves drilling vias 180, 181 in the material 16 as well as drawing over the surface of the material 16 lines (traces or tracks) intended to couple selected ones of the vias 180, 181 according to a desired routing pattern.

A plating step is used to grow metallic (e.g., copper) material on the activated regions 180, 181, 182 thus providing an electrical coupling between the die 14 and the leads 12B.

Devices thus obtained can then be singulated as indicated by line B in FIG. 1D and mounted on a substrate such as a printed circuit board (PCB—not visible in the figures), using solder material, for instance.

In so far as discussed in the foregoing, processing as illustrated in FIGS. 1A to 1D can be regarded as known in the art (see, e.g., the commonly assigned applications cited in the foregoing), which makes it unnecessary to provide a more detailed description herein.

Laser beam operation to structure (drill and/or draw) the regions 180, 181, 182 is facilitated by adequate knowledge of the location of the chips 14 (and the die bonding pads thereon) and the leads 12B even if these are covered by a molding compound layer 16.

Such a masking effect may undesirably lead to “blind mode” operation of the laser unit LB, with the laser beam source referenced only to reference formations (so-called “fiducials”) on a leadframe strip and unable to take into account the actual positions (and possible rotation) of the semiconductor chip.

Laser blindness can be addressed through adaptive patterning, laser process parameters optimization and/or automatic optical inspection of bottom lead vias to identify rejects.

Adaptive patterning only controls die attach (DA) accuracy and cannot compensate leadframe shrinkage after mold.

For instance, leadframe strip mapping after die attachment may be considered for gaining information on the actual location and orientation of each die on the leadframe: automated optical inspection (AOI) equipment may capture the real position of the dice after die attach and communicate it to the laser machine that will adapt structuring the vias and lines accordingly.

That step increases the time and cost of the assembly flow, and is unable to take into account possible shrinkage effects induced on the leadframe by the LDS molding compound: these effects come into play only after an AOI equipment has gathered information on the actual location and orientation of each chip on the leadframe.

Laser process optimization is likewise directly linked to the minimum value of UPH desired in production: ablating more material involves slowing down the whole process

Any other points left apart, automatic visual inspection involves an additional process step.

Commonly-assigned document US 2021/050226 A1 (already cited) and Italian Patent application 102021000014198 (not yet available to the public at the time of filing the instant application and to which U.S. patent application Ser. No. 17/752,503—inventor: Andrea Albertinetti—corresponds) describe methods that facilitate the alignment of a laser machine with respect to the die 14 covered by the molding compound layer 16.

The methods described in these documents essentially involve providing electrically conductive protrusions at the front surface (that is, opposite to the substrate) of the die with their distal ends left exposed at the front surface of the molding compound, thus providing reference points (fiducials) for the alignment of the laser unit with respect to the die.

While satisfactory, these solutions can be further improved as regards gathering information about the actual position of the leads 12B: as noted, the leadframe 12 may shrink as a consequence of the compressive molding step (as illustrated, for example, in FIG. 1C).

Solutions as described herein are based on leadframe modifications which leave regions of the leadframe exposed on the (first) molding compound surface, thus providing reference points which facilitate the alignment of the laser.

Also, in solutions as described herein at least some through mold vias can be provided to the leads without laser drilling.

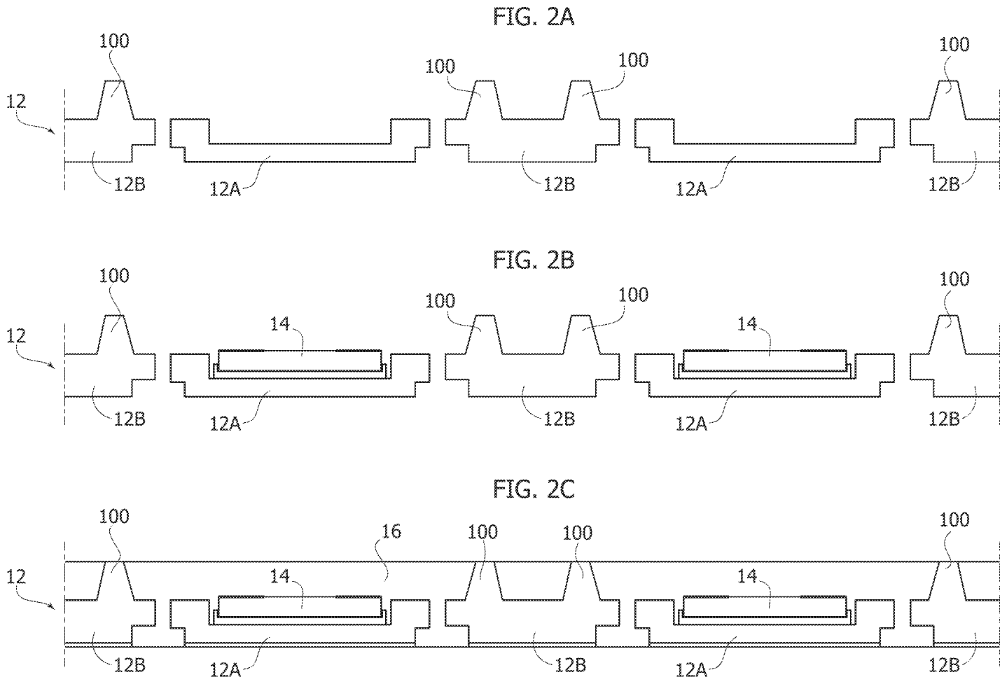

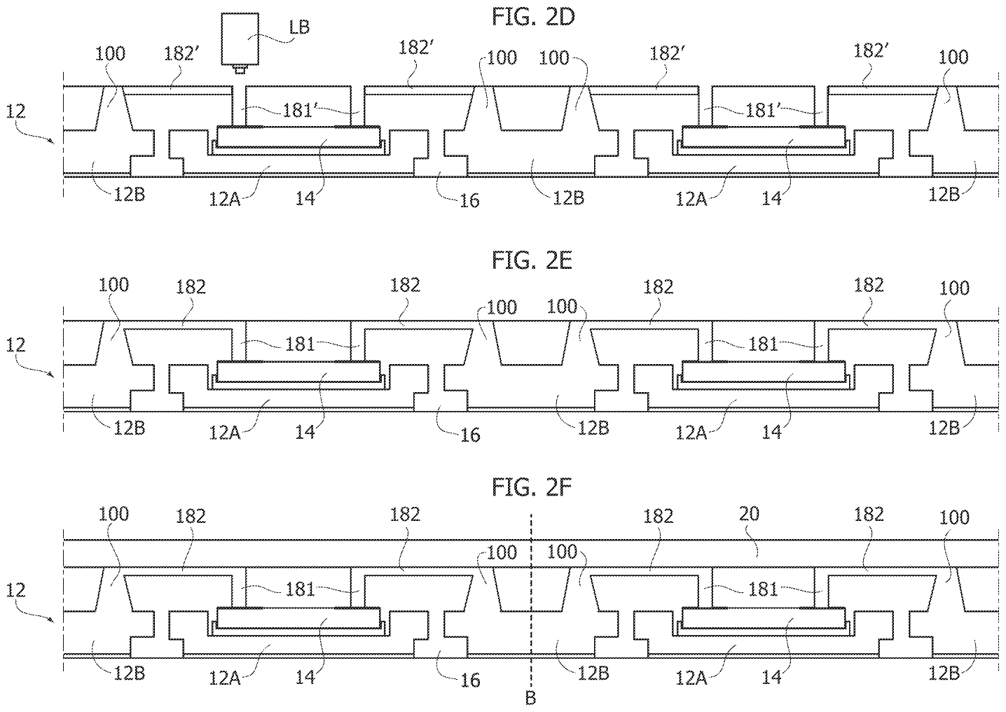

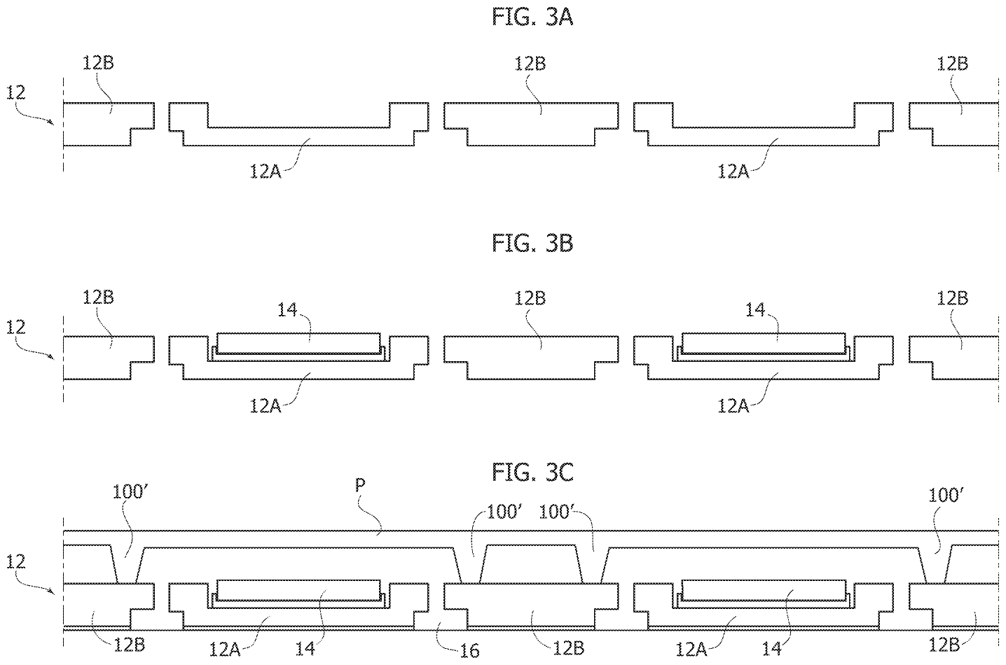

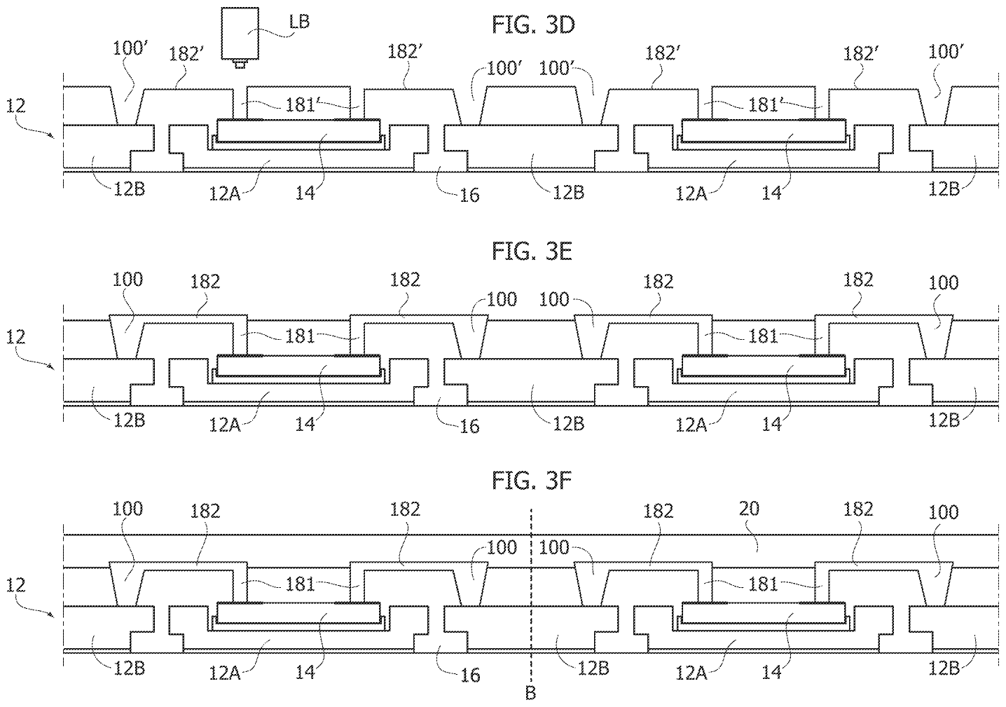

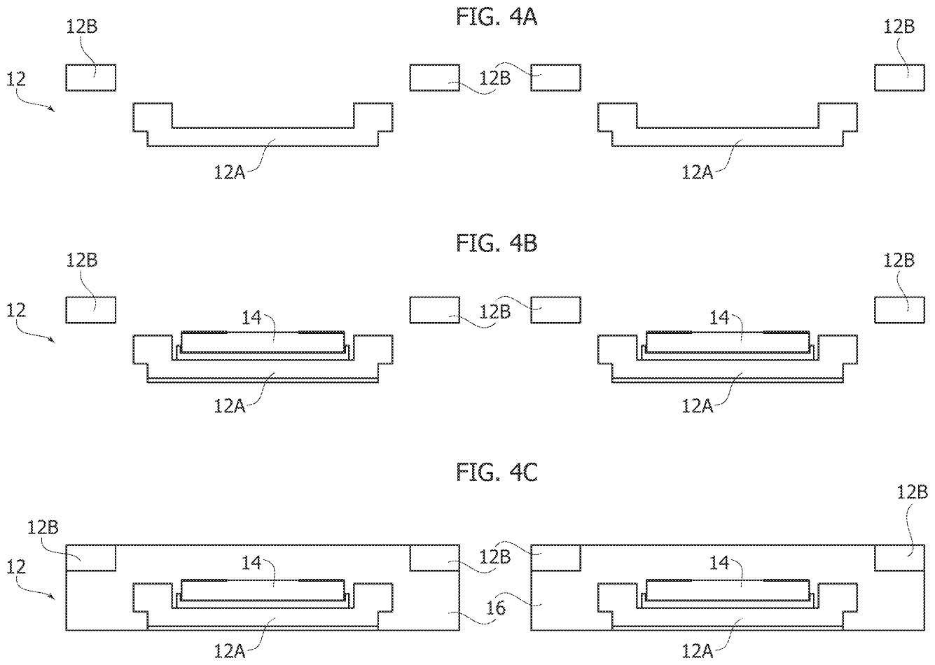

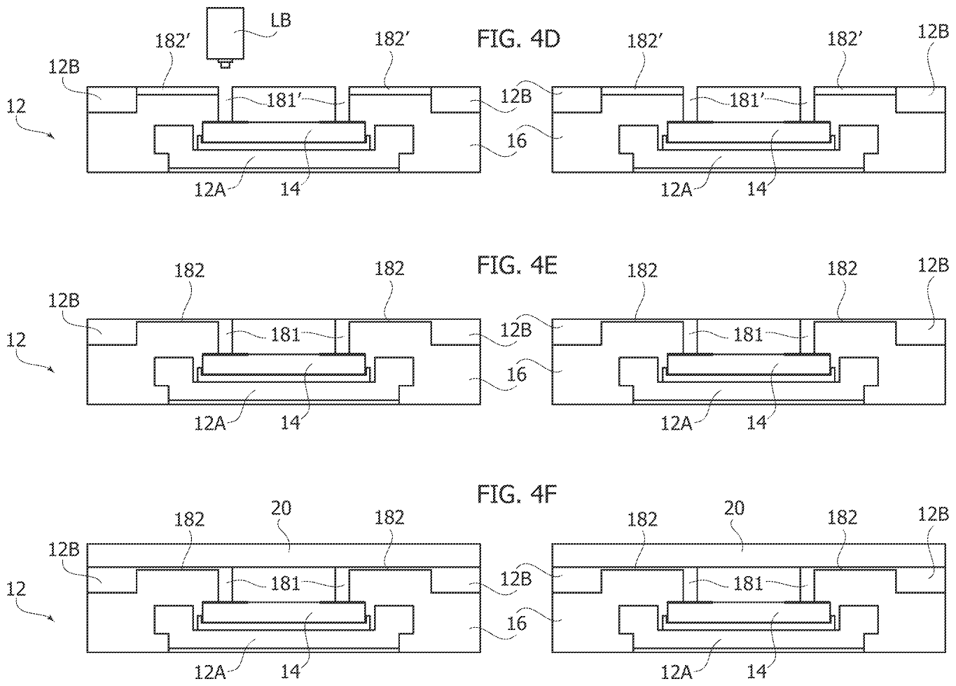

Such a result can be achieved in various alternative ways, e.g.:
providing a leadframe with “pillars” formed thereon (before a molding step), as exemplified in FIGS. 2A to 2F;
inserting punches in a mold chase used to form vias to the leads during a molding step, as exemplified in FIGS. 3A to 3F; and/or
taking advantage of a downset of the die pads with respect to the leads (as exemplified in FIGS. 4A to 4F).

FIGS. 2A to 2F are illustrative of a sequence of steps according to a first embodiment of the present description.

It will be otherwise appreciated that the sequence of FIGS. 2A to 2F (as well as the sequences of FIGS. 3A to 3F and 4A to 4F) is merely exemplary in so far as:
one or more steps illustrated in the figures can be omitted, performed in a different manner (with other tools, for instance) and/or replaced by other steps;
additional steps may be added; and
one or more steps can be carried out in a sequence different from the sequence illustrated.

Corresponding numerals and symbols in FIGS. 2A to 2F, 3A to 3F and 4A to 4F (as well as FIGS. 1A to 1D) generally refer to corresponding parts unless otherwise indicated.

In FIG. 2A is illustrative of a leadframe 12 strip.

The strip 12 can be of a type suited for use with Laser Induced Strip Interconnection, LISI technology having a thickness in the range 200 to 250 microns.

In contrast with such convention LISI leadframes, the leadframe 12 of FIG. 2A is provided with “pillars” 100 located, e.g., on the leads 12B.

The positions and shapes/sizes of the pillars 100 can be suitably devised according to device design and application.

For instance, the height or length (here, vertical extension) of the pillars 100 may be chosen based on the thickness of the dice 14, thus facilitating the process described in the following.

Pillars such as the pillars 100 can be provided via conventional processes, e.g., by copper electroplating or by forming during leadframe stamping, while forming the leadframe 12.

FIG. 2B is illustrative of dice 14 being attached on the die pads 12A, optionally at recessed portions of the die pads 12A.

Such a step may be performed by using die attach material as known per se to those of skill in the art.

FIG. 2C is illustrative of a (first) molding step wherein an LDS molding compound 16 (i.e., with LDS additives) is molded onto the leadframe 12 having the dice 14 attached thereon.

The thickness of the molding compound 16 is adjusted in such a way to leave the upper/distal ends of the pillars 100 exposed at the front (top) surface of the molding compound, thus at the front (top) surface assembly thus obtained.

The exposed tips of the pillars 100 provide reference points or fiducials which facilitate the alignment of the laser source LB during subsequent laser structuring/activation (drilling/scanning) step as represented in FIG. 2D.

FIG. 2D is illustrative of processing where the holes 181′ for vias are drilled in the molding compound 16, providing a path from the front/top surface of the molding compound 16 (the first layer molded in the step illustrated in FIG. 2C) to bonding pads (not visible in the figures for scale reasons) located on the front (top) surface of the dice 14.

In addition, lines referred to as 182′ in FIG. 2D are “drawn” via laser beam over the surface of the LDS material extending at the front (top) surface of the molding compound 16 to connect selected ones of the regions 181′ to the upper ends of selected ones of the pillars 100 to provide a desired routing pattern.

Laser beam processing of the regions 181′, 182′ activates the additives in the LDS compound, thus facilitating the deposition of a metallic layer in these regions.

These locations are indicated by numbers with an accent “′” in order to highlight the fact that electrically conductive vias 181 and traces 182 will be formed at those locations (only) after the subsequent metal growth as represented in FIG. 2E.

FIG. 2E is illustrative of the vias 181 and traces 182 being formed by growing—in a manner known per se to those of skill in the art—metallic material (e.g., copper) in the region 181′, 182′ formed by laser beam processing LB of the LDS molding compound 16.

Such a metallic layer may have a thickness, for example, between 50 microns and 70 microns and can be grown, for example, via electroplating process.

The electrically conductive paths thus formed, comprising the vias 181, the traces 182 and the pillars 100, provide electrical coupling between the dice 14 (e.g., at die bonding pads on the front/top surface thereof—not visible in the figures) and the leads 12B in the leadframe 12.

FIG. 2F is illustrative of a second molding step which completes the plastic body of the device. In this case a standard (that is, non-LDS) molding compound 20 (e.g., an epoxy resin) can be used.

FIGS. 3A and 3B are illustrative of dice 14 mounted on a conventional leadframe 12 (no pillars 100), e.g., at recessed areas of die pads 12A strip and a die 14 mounted thereon.

FIG. 3C is illustrative of a first molding step where an LDS molding compound 16 is molded (using, as otherwise conventional in the art, a mold chase only partly visible in the figures) on the leadframe 12 having the dice 14 arranged thereon.

As illustrated, punches P are provided in the mold chase during molding. The punches P are positioned and shaped in such a way to form cavities referred to as 100′. Again, the accent “′” is used to highlight the fact that the cavities 100′ are formed at locations where vias to the leads 12B will be formed.

The shape of the punches P, and thus the shape and the position of the cavities 100′, can be selected according to device design or application.

Once molding completed, with punches P removed, the cavities 100′ will provide a path from the front or top surface of the molding compound 16 to the die bonding pads (not visible) on the front or top surface of the die 14 and, in addition, provide a reference point which facilitates the alignment of the laser with respect to the leadframe.

It is noted that the punch height or depth can be designed to generate partial vias, sufficient to facilitate alignment (of the laser LB— see FIG. 3D) on the leadframe.

FIG. 3D is illustrative of a processing step wherein holes 181′ for vias are formed by laser drilling the molding compound 16, thus providing a path from the front/top surface of the molded compound 16 (the first layer molded in the step illustrated in FIG. 3C) to bonding pads (not visible in the figures for scale reasons) located on the front (top) surface of the dice 14.

Punches such as the punches P might be notionally adopted also to provide holes 181′ for vias such as the vias 181.

That approach may not be advantageous in view of possible damage to the semiconductor (silicon) and due to alignment issues.

In fact, the tolerance inherent in the level at which the bonding pads are located may be fairly large due to, e.g., variability in the thicknesses of the semiconductor (silicon), the die attach material and the leadframe. Conversely, in the case of the cavities 100′ (vias 100) only tolerances related to the leadframe come into play and possible errors result, at most, in moderate scoring of the leadframe, having no impact on the subsequent processes.

Possible variability of the position of the die after die attachment would also adversely affect proper centering of the die pads if punches (a “by design” solution) are used.

As exemplified herein, the walls of the cavities 100′ formed with the punches P are laser-activated in order to facilitate subsequent metallization (e.g., copper growth).

Lines referred to as 182′ in FIG. 3D are “drawn” via laser beam LB over the surface of the LDS material extending at the front (top) surface of the molding compound 16 to connect selected ones of the regions 181′ to the upper ends of selected ones of the pillars 100 to provide a desired routing pattern.

A (frusto)conical shape of the cavities 100′ as shown is otherwise merely exemplary and non-mandatory: in fact the punches P (and, in a complementary way) the cavities 100′ may be shaped with different shapes.

In the mentioned case where “partial” cavities 100′ are formed (with punch height sufficient to facilitate alignment on the leadframe) further laser drilling would be performed in order for the cavities 100′ to reach the leads 12B.

FIG. 3E is illustrative of the deposition (e.g., via electroplating) of a metallic (e.g., copper) layer in the regions 100′, 181′ and 182′ formed in the steps illustrated in FIGS. 3C and 3D.

Similar to the previous case, such a metallic layer may have a thickness, for example, between 50 microns and 70 microns.

The electrically conductive path thus formed, comprising the vias 181, the traces 182 and the “filled” cavities 100, provide electrical coupling between the die bonding pads (not visible in the figures) on the front/top surface of the die 14 end the leads 12B in the leadframe 12.

FIG. 3F is illustrative of a second molding step (possibly, with a non-LDS compound, e.g., epoxy resin) 20 which completes the plastic body of the device.

FIG. 4A illustrates a leadframe strip 12 wherein the die pads 12A are “downset” (e.g., by 50 microns) with respect to the leads 12B. Such a feature has been already adopted for certain leadframes for devices such as, e.g., Exposed Pad Quad Flat Pack, QFP-EP packages.

FIG. 4B illustrates the mounting of dice 14 on the die pads 12A of the leadframes 12 (e.g., at recessed portions thereof) of FIG. 4A.

FIG. 4C is illustrative of a first molding step where LDS molding compound 16 is molded on the leadframe 12 with the dice 14 attached thereon. The thickness of the molding compound may be chosen in such a way to leave the elevated leads 12B exposed at the surface of the molded assembly.

The elevated (exposed) leads 12B serve as “fiducials”, that is reference points, for the alignment of a laser LB (see FIG. 4D), thus facilitating subsequent processing steps.

FIG. 4D illustrates a processing step (similarly to what has been discussed in FIGS. 2D and 3D) wherein holes 181′ for vias are formed, providing a path from the front/top surface of the molded compound 16 (the first layer molded in the step illustrated in FIG. 2C) to the bonding pads (not visible in the figures for scale reasons) located on the front (top) surface of the dice 14.

Lines or traces 182′ are also “drawn” by laser beam LB over the front (top) surface of the molding compound to connect selected ones of the regions 181′ to selected ones of the elevated leads 12B.

FIG. 4E is illustrative of the holes 181′ and the regions 182′ being filled (via, e.g., electroplating) with metallic material (copper) to form vias 181 and traces 182 which provide the electrical coupling between the die bonding pad on the front/top surface of the dice 14 and the elevated leads 12B.

FIG. 4F is illustrative of a second molding step (possibly with a non-LDS material, e.g., epoxy resin 20) which completes the plastic body of the device.

Further processing steps, common to the solutions described in FIGS. 2A to 2F, FIGS. 3A to 3F, and FIGS. 4A to 4F, may include:
a tin plating step to form a tin layer on the back/bottom surface of the die pad 12A and leads 12B, and
a singulation step wherein the device strip is cut.

Without prejudice to the underlying principles, the details and the embodiments may vary, even significantly, with respect to what has been described by way of example only without departing from the scope of the embodiments.

A method may be summarized as including: arranging at least one semiconductor die (14) on a die pad (12A) in a leadframe (12), the leadframe (12) including an array of electrically conductive leads (12B) around the die pad (12A), molding laser direct structuring, LDS material (16) onto the at least one semiconductor die (14) arranged on said die pad (12A), the LDS material (16) having a front surface opposite the leadframe (12), electrically coupling the at least one semiconductor die (14) arranged on said die pad (12A) with selected ones of the electrically conductive leads (12B) in said array via electrical connections, wherein the electrical connections include: electrically conductive formations (100) exposed at the front surface of the LDS material (16), electrically conductive vias (181) between the at least one semiconductor die (14) arranged on said die pad (12A) and the front surface of the LDS material (16), as well as electrically conductive lines (182) over the front surface of the LDS material (16), the electrically conductive lines (182) coupling selected ones of the electrically conductive formations (100) with selected ones of the electrically conductive vias (181), wherein: providing said electrically conductive vias (181) and said electrically conductive lines (182) includes applying laser beam energy (LB) to the front surface of the laser direct structuring material (16) at spatial positions (181′, 182′) located as a function of said electrically conductive formations (100) exposed at the front surface of the LDS material.

The electrically conductive formations (100) exposed at the front surface of the LDS material (16) may include pillar-like extensions (100) of the electrically conductive leads (12B) in said array, with the LDS material (16) molded onto the at least one semiconductor die (14) arranged on said die pad (12A) leaving uncovered the distal ends of said pillar-like extensions (100).

The method may include: molding LDS material (16) onto the at least one semiconductor die (14) arranged on said die pad (12A) using a mold provided with punches (P) protruding towards electrically conductive leads (12B) in said array wherein the molded LDS material exhibits cavities (100′) in the front surface of the LDS material (16) extending towards electrically conductive leads (12B) in said array, and growing electrically conductive material in said cavities (100′), wherein the electrically conductive material grown in said cavities (100′) provides electrically conductive formations (100) grown on electrically conductive leads (12B) in said array, said electrically conductive formations (100) exposed at the front surface of the LDS material.

The electrically conductive formations (100) exposed at the front surface of the LDS material may include electrically conductive leads (12B) in said array, wherein said die pad (12A) is downset with respect to said electrically conductive leads (12B) in said array.

The method may include growing electrically conductive material at said spatial positions (181′, 182′) located as a function of said electrically conductive formations (100) exposed at the front surface of the LDS material to which laser beam energy (LB) has been applied.

Said growing electrically conductive material may include plating metal material, preferably copper.

A leadframe (12) for use in the method may be summarized as including a die pad (12A) configured to have at least one semiconductor die (14) arranged thereon and an array of electrically conductive leads (12B) around the die pad (12A), the leadframe (12) comprising pillar-like extensions (100) of the electrically conductive leads (12B) in said array, the pillar-like extensions (100) of the electrically conductive leads (12B) configured to have an LDS material (16) molded thereon leaving uncovered the distal ends of said pillar-like extensions (100).

A mold for molding LDS material (16) onto the at least one semiconductor die (14) in the method, wherein the mold may be provided with punches (P) protruding towards electrically conductive leads (12B) in said array, wherein the punches (P) may form in the molded LDS material said cavities (100′) in the front surface of the LDS material (16) extending towards electrically conductive leads (12B) in said array to have electrically conductive material grown therein.

A semiconductor device may be summarized as including: at least one semiconductor die (14) arranged on a die pad (12A) in a leadframe (12), the leadframe (12) comprising an array of electrically conductive leads (12B) around the die pad (12A), laser direct structuring, LDS material (16) molded onto the at least one semiconductor die (14) arranged on said die pad (12A), the LDS material (16) having a front surface opposite the leadframe (12), electrical connections electrically coupling the at least one semiconductor die (14) arranged on said die pad (12A) with selected ones of the electrically conductive leads (12B), wherein the electrical connections comprise: electrically conductive formations (100) exposed at the front surface of the LDS material, electrically conductive vias (181) between the at least one semiconductor die (14) arranged on said die pad (12A) and the front surface of the LDS material (16), as well as electrically conductive lines (182) over the front surface of the LDS material (16), the electrically conductive lines (182) coupling selected ones of the electrically conductive formations (100) with selected ones of the electrically conductive vias (181), wherein: said electrically conductive vias (181) and said electrically conductive lines (182) comprises laser beam activated (LB) regions of the front surface of the laser direct structuring material (16) located at spatial positions (181′, 182′) spatially referenced to said electrically conductive formations (100) exposed at the front surface of the LDS material.

The electrically conductive formations (100) exposed at the front surface of the LDS material (16) may include: pillar-like extensions (100) of the electrically conductive leads (12B) in said array, with the LDS material (16) molded onto the at least one semiconductor die (14) arranged on said die pad (12A) leaving uncovered the distal ends of said pillar-like extensions (100); or electrically conductive material grown on electrically conductive leads (12B) in said array in cavities (100′) in the front surface of the LDS material (16) extending towards electrically conductive leads (12B) in said array; or electrically conductive leads (12B) in said array, wherein said die pad (12A) is downset with respect to said electrically conductive leads (12B) in said array.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
arranging at least one semiconductor die on a die pad in a leadframe, the leadframe comprising an array of electrically conductive leads around the die pad;
molding laser direct structuring (LDS) material onto the at least one semiconductor die arranged on the die pad, the LDS material having a front surface opposite the leadframe;
electrically coupling the at least one semiconductor die arranged on the die pad with selected ones of the electrically conductive leads in the array via electrical connections, wherein the electrical connections comprise:
electrically conductive formations exposed at the front surface of the LDS material;
electrically conductive vias between the at least one semiconductor die arranged on the die pad and the front surface of the LDS material; and
electrically conductive lines over the front surface of the LDS material, the electrically conductive lines coupling selected ones of the electrically conductive formations with selected ones of the electrically conductive vias,
wherein the providing the electrically conductive vias and the electrically conductive lines comprises applying laser beam energy to the front surface of the laser direct structuring material at spatial positions located as a function of the electrically conductive formations exposed at the front surface of the LDS material.

2. The method of claim 1, wherein the electrically conductive formations exposed at the front surface of the LDS material comprise pillar-like extensions of the electrically conductive leads in the array, with the LDS material molded onto the at least one semiconductor die arranged on the die pad leaving uncovered the distal ends of the pillar-like extensions.

3. The method of claim 1, comprising:
molding LDS material onto the at least one semiconductor die arranged on the die pad using a mold provided with punches protruding towards electrically conductive leads in the array wherein the molded LDS material exhibits cavities in the front surface of the LDS material extending towards electrically conductive leads in the array, and
growing electrically conductive material in the cavities, wherein the electrically conductive material grown in the cavities provides electrically conductive formations grown on electrically conductive leads in the array, the electrically conductive formations exposed at the front surface of the LDS material.

4. The method of claim 1, wherein the electrically conductive formations exposed at the front surface of the LDS material comprise electrically conductive leads in the array, wherein the die pad is downset with respect to the electrically conductive leads in the array.

5. The method of claim 1, comprising growing electrically conductive material at the spatial positions located as a function of the electrically conductive formations exposed at the front surface of the LDS material to which laser beam energy has been applied.

6. The method of claim 3, wherein the growing electrically conductive material comprises plating metal material, preferably copper.

7. The method of claim 2, wherein the pillar-like extensions of the electrically conductive leads in the array have a first height that is equal to a first depth of the LDS material molded onto at least one semiconductor die.

8. The method of claim 3, wherein the punches form in the molded LDS material the cavities in the front surface of the LDS material extending towards electrically conductive leads in the array.

9. A semiconductor device, comprising:
at least one semiconductor die arranged on a die pad in a leadframe, the leadframe comprising an array of electrically conductive leads around the die pad;
laser direct structuring (LDS) material molded onto the at least one semiconductor die arranged on the die pad, the LDS material having a front surface opposite the leadframe;
electrical connections electrically coupling the at least one semiconductor die arranged on the die pad with selected ones of the electrically conductive leads, wherein the electrical connections comprise:
electrically conductive formations exposed at the front surface of the LDS material;
electrically conductive vias between the at least one semiconductor die arranged on the die pad and the front surface of the LDS material; and
electrically conductive lines over the front surface of the LDS material, the electrically conductive lines coupling selected ones of the electrically conductive formations with selected ones of the electrically conductive vias,
wherein the electrically conductive vias and the electrically conductive lines comprise laser beam activated regions of the front surface of the laser direct structuring material located at spatial positions spatially referenced to the electrically conductive formations exposed at the front surface of the LDS material.

10. The semiconductor device of claim 9, wherein the electrically conductive formations exposed at the front surface of the LDS material comprise pillar-like extensions of the electrically conductive leads in the array, with the LDS material molded onto the at least one semiconductor die arranged on the die pad leaving uncovered the distal ends of the pillar-like extensions.

11. The semiconductor device of claim 9, wherein the electrically conductive formations exposed at the front surface of the LDS material comprise electrically conductive material grown on electrically conductive leads in the array in cavities in the front surface of the LDS material extending towards electrically conductive leads in the array.

12. The semiconductor device of claim 9, wherein the electrically conductive formations exposed at the front surface of the LDS material comprise electrically conductive leads in the array, wherein the die pad is downset with respect to the electrically conductive leads in the array.

13. A method, comprising:
forming a die on a recessed portion of a die pad in a leadframe, the leadframe comprising a plurality of electrically conductive leads surrounding the die pad;
forming a mold chase on the leadframe, the mold chase including a plurality of punches that are coupled directly to the electrically conductive leads;
forming a laser direct structuring (LDS) molding compound between the mold chase and the leadframe, the LDS molding compound having a first surface coupled to the leadframe and a second surface opposite the first surface;
removing the mold chase to expose a plurality of cavities extending from the second surface of the LDS molding compound to the electrically conductive leads; and
forming a conductive layer in the plurality of cavities and on the second surface of the LDS molding compound.

14. The method of claim 13, comprising, before the forming a conductive layer, forming a plurality of vias from the second surface of the LDS molding compound to the die.

15. The method of claim 14, wherein the plurality of vias are formed using a laser drilling through the LDS molding compound.

16. The method of claim 14, wherein the die includes a plurality of bonding pads and each of the plurality of vias extends from the second surface of the LDS molding compound to one of the plurality of bonding pads on the die.

17. The method of claim 14, comprising forming, with a laser, a plurality of traces on the second surface of the LDS molding compound, the traces extending from one of the plurality of vias to an adjacent one of the trenches.

18. The method of claim 17, wherein the conductive layer is formed in the plurality of vias and in the plurality of traces, the conductive layer coupling each trench to an adjacent one of the plurality of vias along one of the plurality of traces.

19. The method of claim 13, wherein the forming a conductive layer in the plurality of cavities and on the second surface of the LDS molding compound includes depositing metal into the plurality of cavities and on the second surface of the LDS molding compound.

20. The method of claim 13, comprising forming an insulating layer on the second surface of the LDS molding compound.
